(19) United States
(12) Patent Application Publication
(10) Pub. No.: US 2022/0302343 A1
(43) Pub. Date: Sep. 22, 2022

(54) LIGHT EMITTING ELEMENT

(71) Applicant: ABOCOM SYSTEMS, INC., Miaoli County (TW)

(72) Inventors: Cheng-Yi OU, Miaoli County (TW); Chih-Yuan LIN, Miaoli County (TW); Te-Lieh PAN, Miaoli County (TW); Cheng-Hsiao CHI, Miaoli County (TW)

(21) Appl. No.: 17/573,643

(22) Filed: Jan. 12, 2022

(30) Foreign Application Priority Data
Mar. 16, 2021 (TW) 110109441

(51) Int. Cl. H01L 33/04; H01L 33/38; H01L 33/00

(52) U.S. Cl. CPC H01L 33/04; H01L 33/382; H01L 33/0012

(57) ABSTRACT

A light emitting element includes a substrate, a lower cladding layer, a lower confinement layer, an active layer, an upper confinement layer, an upper cladding layer, a tunnel junction layer, a window layer and an upper electrode sequentially arranged from bottom to top. The tunnel junction layer is for converting the window layer and upper electrode from the p-type of a traditional LED to the n-type of the light emitting element of this disclosure. Since the n-type window layer has a resistance much smaller than that of the p-type window layer, the window layer of this disclosure has low resistance and good current spreading effect to improve the light emitting efficiency. Since the n-type upper electrode has a resistance much lower than that of the p-type upper electrode, the n-type upper electrode of this disclosure is more conducive to ohmic contact than the p-type upper electrode of the traditional LED.

### CROSS-REFERENCE TO RELATED APPLICATIONS

This non-provisional application claims priority under 35 U.S.C. § 119(a) on Patent Application No(s). 110109441 filed in Taiwan, R.O.C. on Mar. 16, 2021, the entire contents of which are hereby incorporated by reference.

### BACKGROUND

### Technical Field

The present disclosure relates to a light emitting element having a window layer with a good current spreading effect.

### Description of Related Art

Optical semiconductor devices such as light emitting elements include light emitting diodes (LEDs) and laser diodes (LDs), and the light emitting element forms a p-n junction or a p-i-n junction on the semiconductor substrate by epitaxy technology to achieve the light emitting effect. In general, a traditional light emitting element (such as LED) is formed by epitaxy and its structure includes: a substrate, a distributed Bragg reflector (DBR) layer, a lower cladding layer, a lower confinement layer, an active layer, an upper confinement layer, an upper cladding layer and a window layer, which are sequentially arranged from bottom to top. In addition, there are two contact layers such as a lower electrode and an upper electrode, wherein the bottom of the substrate is the lower electrode, and the top of the window layer is formed into the upper electrode, and the lower electrode and the upper electrode are formed with the substrate and the window layer into an ohmic contact to supply electric energy to the active layer and inject carriers. The lower electrode, the substrate, the DBR layer and the lower cladding layer are of the first conductive type such as an n-type, and the upper electrode, the window layer and the upper cladding layer are of the second conductive type such as a p-type, and the lower confinement layer, the active layer and the upper confinement layer are undoped. For example, the epiwafer structure of the aluminium gallium indium phosphide (AlGaInP) series LED includes a lower confinement layer composed of an n-type DBR layer, an n-type lower cladding layer, and an undoped AlGaInP layer sequentially grown on an n-type gallium arsenide (GaAs) substrate, and an active layer and an upper confinement layer are coupled to a p-type upper cladding layer, and a p-type window layer made of gallium phosphide (GaP), and coupled to a p-type upper electrode made of GaP.

In general, the window layer serves as a current spreading layer, wherein the high conductivity (low resistance) of the window layer is used to spread the current horizontally to improve the light emitting efficiency of the LED. The window layer of the traditional LED is a p-type window layer with magnesium doping in order to improve the conductivity and use the doping concentration of 9.0×10¹⁷ atoms/cm³ to perform the magnesium (Mg) doping, but the magnesium doping concentration of the p-type window layer has an upper limit of only 3.0×10¹⁸ atoms/cm³. In other words, the p-type window layer with magnesium doping of the current LED is unable to further lower the resistance. In addition, another issue of using magnesium for doping is that the use of magnesium doping has a memory effect easily, thereby making it difficult to control and maintain the background environment, concentration setting parameter, and related process conditions in the reaction chamber of the epitaxy process.

The p-type window layer is accompanied by the p-type upper electrode, which is n p-type ohmic contact layer, and a high doping concentration is generally used for the carbon (C) doping to achieve the low resistance requirement, such as 1.0×10¹⁹ atoms/cm³, but the high carbon doping concentration is also difficult to control in the manufacturing process.

### SUMMARY

In view of the problems of the prior art, it is a primary objective of the present disclosure to provide a light emitting element having a window layer with lower resistance and good current spreading to improve the light emitting efficiency, and control the manufacturing process of the window layer and an upper electrode easily.

To achieve the foregoing and other objectives, the present disclosure converts the p-type window layer of the traditional LED into an n-type and discloses a light emitting element of the present disclosure.

The light emitting element of the present disclosure includes: a lower cladding layer, disposed at the top of the substrate; a lower confinement layer, disposed at the top of the lower cladding layer; an active layer, disposed at the top of the lower confinement layer; an upper confinement layer, disposed at the top of the active layer; an upper cladding layer, disposed at the top of the upper confinement layer; a tunnel junction layer, disposed at the top of the upper cladding layer; and a window layer, being an n-type window layer, disposed at the top of the tunnel junction layer.

In another embodiment, the tunnel junction layer includes a heavily-doped p-type layer and a heavily-doped n-type layer, and the heavily-doped n-type layer is disposed adjacent to and at the top of the heavily-doped p-type layer.

In another embodiment, the heavily-doped p-type layer is disposed adjacent to and at the top of the upper cladding layer, and the window layer is disposed adjacent to and at the top of the heavily-doped n-type layer.

In another embodiment, an upper electrode and the window layer form an ohmic contact, and the upper electrode is an n-type electrode.

Another light emitting element of the present disclosure includes: a substrate; a tunnel junction layer, disposed at the top of the substrate; a lower cladding layer, disposed at the top of the tunnel junction layer; a lower confinement layer, disposed at the top of the lower cladding layer; an active layer, disposed at the top of the lower confinement layer; an upper confinement layer, disposed at the top of the active layer; and an upper cladding layer, disposed at the top of the upper confinement layer; a window layer, disposed at the top of the upper cladding layer.

In another embodiment, the tunnel junction layer includes a heavily-doped p-type layer and a heavily-doped n-type layer, and the heavily-doped p-type layer is disposed adjacent to and at the top of the heavily-doped n-type layer.

In another embodiment, the heavily-doped n-type layer is disposed at the top of the substrate, and the lower cladding layer is disposed adjacent to and at the top of the heavily-doped n-type layer.

### BRIEF DESCRIPTION OF THE DRAWINGS

FIG. 1 is a cross-sectional view of a light emitting element in accordance with a first embodiment of the present disclosure; and

FIG. 2 is a cross-sectional view of a light emitting element in accordance with a second embodiment of the present disclosure.

### DESCRIPTION OF THE EMBODIMENTS

This disclosure will now be described in more detail with reference to the accompanying drawings that show various embodiments of this disclosure.

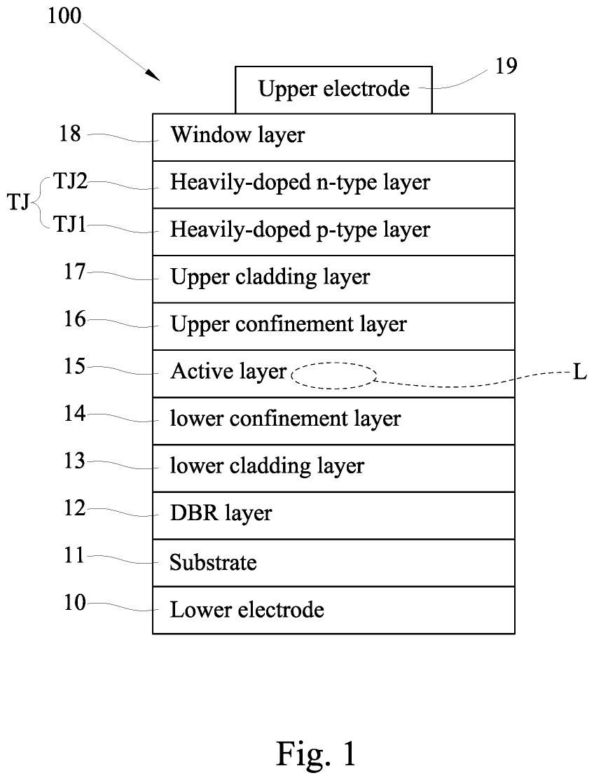

With reference to FIG. 1 for a light emitting element of the present disclosure, the light emitting element 100 can be a light emitting diode (LED) or a laser diode (LD). In order to facilitate the understanding of the spirit of the present disclosure, the following embodiments adopt the structure of the LED as an example, but people having ordinary skill in the art should understand that the spirit and structure of the present disclosure are also applicable to the LD. In the first implementation mode, the light emitting element 100 includes: a lower electrode 10; a substrate 11, contacted with the lower electrode 10 and disposed at the top or the bottom of the lower electrode 10; a DBR layer 12, disposed at the top of the substrate 11 and contacted with an upper surface of the substrate 11; a lower cladding layer 13 disposed at the top of the DBR layer 12 and contacted with an upper surface of the DBR layer 12; a lower confinement layer 14, disposed at the top of the lower cladding layer 13 and contacted with an upper surface of the lower cladding layer 13; an active layer 15, disposed at the top of the lower confinement layer 14 and contacted with an upper surface of the lower confinement layer 14; an upper confinement layer 16, disposed at the top of the active layer 15 and contacted with an upper surface of the active layer 15; an upper cladding layer 17, disposed at the top of the upper confinement layer 16 and contacted with an upper surface of the upper confinement layer 16; a tunnel junction layer TJ, disposed at the top of the upper cladding layer 17 and contacted with an upper surface of the upper cladding layer 17; a window layer 18, disposed at the top of the tunnel junction layer TJ and contacted with an upper surface of the tunnel junction layer TJ; an upper electrode 19, disposed at the top of the window layer 18 and contacted with an upper surface of the window layer 18. The lower electrode 10 and the upper electrode 19 are contact layers, and the lower electrode 10 and the upper electrode 19 are formed with the substrate 11 and the window layer 18 into the ohmic contacts respectively to supply electric energy to the active layer 15 and inject carriers. In other words, the structure of the light emitting element 100 includes: the substrate 11, the DBR layer 12, the lower cladding layer 13, the lower confinement layer 14, the active layer 15, the upper confinement layer 16, the upper cladding layer 17, the tunnel junction layer TJ, the window layer 18 and the upper electrode 19, which are sequentially grown from bottom to top by an epitaxy technology such as molecular beam epitaxy (MBE), metal organic vapor phase epitaxy (MOPVE), low pressure vapor phase epitaxial method (LPMOVPE) or metal organic chemical vapor deposition (MOCVD) in-situ in the reaction chamber. Of course, the DBR layer 12 may be omitted, and the lower cladding layer 13 is disposed at the top of the substrate 11 and contacted with an upper surface of the substrate 11.

The first electrode 10 is a first conductive electrode such as an n-type electrode. The substrate 11 is a first conductive substrate such as an n-type gallium arsenide (GaAs) substrate. The DBR layer 12 is a first conductive DBR layer such as an n-type DBR layer, which can be aluminium gallium arsenide (AlGaAs) layer. The lower cladding layer 13 is a first conductive cladding layer such as the n-type cladding layer, and the lower cladding layer 13 can be made of aluminium indium phosphide (AlInP). The lower confinement layer 14 is made of a material such as (AlxGa1-x) 0.5In0.5P, wherein 0<x<1, such as 0.65. The active layer 15 can be a light emitting layer with a multi-quantum well structure, and the multi-quantum well structure is formed by repeatedly stacking a plurality of stack pairs (not shown in the figure), and each stack pair includes a well layer and an energy barrier layer. The active layer 15 can be made of a material such as (AlyGa1-y) 0.5In0.5P, wherein 0<y<1, such as 0.65. The upper confinement layer 16 can be made of a material such as (AlzGa1-z) 0.5In0.5P, wherein 0<z<1, such as 0.65. The lower confinement layer 14, the active layer 15 and the upper confinement layer 16 are undoped. The upper cladding layer 17 is a second conductive cladding layer such as the p-type cladding layer, and the upper cladding layer 17 can be made of aluminium indium phosphide (AlInP).

The tunnel junction layer TJ is a multi-layer structure including a second heavily-doped layer and a first heavily-doped layer such as a heavily-doped p-type layer TJ1 and a heavily-doped n-type layer TJ2 respectively, and the heavily-doped n-type layer TJ2 is disposed adjacent to and at the top of the heavily-doped p-type layer TJ1. In other words, the first heavily-doped layer is disposed adjacent to and at the top of the second heavily-doped layer. The heavily-doped p-type layer TJ1 of the tunnel junction layer TJ is disposed at the top of the upper cladding layer 17. For example, the heavily-doped p-type layer TJ1 of the tunnel junction layer TJ is disposed adjacent to the upper cladding layer 17; the window layer 18 is disposed adjacent to and at the top of the heavily-doped n-type layer TJ2. The tunnel junction layer TJ can be made of a material matched with the material of the substrate 11. For example, the substrate 11 is made of GaAs, and the tunnel junction layer TJ can be made of gallium arsenide (GaAs), aluminum gallium arsenide (AlGaAs) indium gallium phosphide (InGaP), aluminum indium phosphide (AlInP), aluminium gallium indium phosphide (AlGaInP) or gallium phosphide (GaP).

The window layer 18 is a first conductive window layer such as the n-type window layer, and the window layer 18 has a wider or indirect energy gap and a higher conductivity, and the window layer 18 can be made of GaP, GaAsP or AlGaAs. The window layer 18 can be made of silicon (Si)-doped GaP with a silicon doping concentration of 1.0×10¹⁸ atoms/cm³.

The upper electrode 19 is a first conductive electrode such as the n-type electrode, and the n-type electrode can be made of a Si/Te doped GaP with a silicon doping concentration greater than 5.0×10¹⁸ atoms/cm³.

Table 1 lists the structural comparison of the traditional LED in accordance with the Comparative Example 1.

TABLE 1
(Comparative Example 1)

| | | | | Dopant Content | |
|---|---|---|---|---|---|
| Layer | Description | Material | Dopant | (atoms/cm³) | Type |
| 1 | Lower electrode | GaAs | Si | Greater than | n |
| | | | | 1.0 × 10¹⁸ | |
| 2 | Substrate | GaAs | Si | Greater than | n |
| | | | | 1.0 × 10¹⁸ | |
| 3 | DBR layer | AlGaAs | Si | 6.0 × 10¹⁷ | n |
| 4 | Lower cladding | AlInP | Si | 6.0 × 10¹⁷ | n |
| | layer | | | | |
| 5 | lower confinement | (Al_{0.65}Ga_{0.35})_{0.5}In_{0.5}P | — | — | — |
| | layer | | | | |
| 6 | Active layer | (Al_{0.65}Ga_{0.35})_{0.5}In_{0.5}P | — | — | — |
| 7 | Upper confinement | (Al_{0.65}Ga_{0.35})_{0.5}In_{0.5}P | — | — | — |
| | layer | | | | |
| 8 | Upper cladding | Al_{0.5}In_{0.5}P | Mg | 9.0 × 10¹⁷ | p |
| | layer | | | | |
| 9 | Window layer | GaP | Mg | 9.0 × 10¹⁷ | p |
| 10 | Upper electrode | GaP | C | 1.0 × 10¹⁹ | p |

Table 2 lists the structural comparison of a light emitting element 100 in accordance with the first embodiment of the present disclosure (which is the first implementation mode)

TABLE 2
(First Embodiment)

| | | | | Dopant Content | |
|---|---|---|---|---|---|
| Layer | Description | Material | Dopant | (atoms/cm³) | Type |
| 1 | Lower electrode | GaAs | Si | Greater than | n |
| | | | | 1.0 × 10¹⁸ | |
| 2 | Substrate | GaAs | Si | Greater than | n |
| | | | | 1.0 × 10¹⁸ | |
| 3 | DBR layer | AlGaAs | Si | 6.0 × 10¹⁷ | n |
| 4 | Lower cladding | AlInP | Si | 6.0 × 10¹⁷ | n |
| | layer | | | | |
| 5 | Lower confinement | (Al_{0.65}Ga_{0.35})_{0.5}In_{0.5}P | — | — | — |
| | layer | | | | |
| 6 | Active layer | (Al_{0.65}Ga_{0.35})_{0.5}In_{0.5}P | — | — | — |
| 7 | Upper confinement | (Al_{0.65}Ga_{0.35})_{0.5}In_{0.5}P | — | — | — |
| | layer | | | | |
| 8 | Upper cladding | Al_{0.5}In_{0.5}P | Mg | 9.0 × 10¹⁷ | p |
| | layer | | | | |
| Tunnel | Heavily-doped | GaP | C | Greater than | p |
| junction | p-type layer | | | 5.0 × 10¹⁹ | |
| layer | Heavily-doped | GaP | Te | Greater than | n |
| | n-type layer | | | 5.0 × 10¹⁹ | |
| 9 | Window layer | GaP | Si | 1.0 × 10¹⁸ | n |
| 10 | Upper electrode | GaP | Si/Te | Greater than | n |
| | | | | 5.0 × 10¹⁸ | |

The light emitting element 100 of the first embodiment of the present disclosure (Table 2) is compared with the traditional LED of the Comparative Example 1 (Table 1). In the first embodiment, the tunnel junction layer TJ is added between the upper cladding layer and the window layer of the Comparative Example 1. Compared with the Comparative Example 1, the first embodiment has the following advantages: (1) The tunnel junction layer TJ of the first embodiment converts the p-type window layer of the Comparative Example 1 into the n-type window layer (which is the aforementioned window layer 18) of the first embodiment. Since the n-type window layer has a resistance much smaller than the resistance of the p-type window layer, the window layer 18 of the first embodiment has a low resistance and a good current spreading effect to improve the light emitting efficiency of the first embodiment. (2) Since the window layer 18 of the first embodiment is an n-type window layer, the upper electrode 19 is also an n-type electrode. In other words, the tunnel junction layer TJ also converts the p-type upper electrode of the Comparative Example 1 into the n-type upper electrode (which is the aforementioned upper electrode 19) of the first embodiment. The n-type upper electrode has a resistance much smaller than the resistance of the p-type upper electrode, so that the upper electrode 19 (or n-type upper electrode) of the first embodiment is more conducive to the ohmic contact compared with the upper electrode (or p-type upper electrode) of the Comparative Example 1. (3) Unexpectedly, it is found that the mobility of carriers in the n-type semiconductor is greater than the mobility of carriers in the p-type semiconductor, so that the electrons/electron holes are coupled to the upper half of the active layer of the Comparative Example 1 to emit light, such that most of the optical field L is deviated at the upper half of the active layer and the lower half of the active layer cannot be utilized effectively. On the other hand, the first embodiment uses the tunnel junction layer TJ to convert the window layer 18 and the upper electrode 19 into the n-type, and thus the carriers of the first embodiment from top to bottom has a mobility at the upper electrode 19 and the window layer 18 greater than the mobility of the carriers of the Comparative Example 1 from top to bottom at the upper electrode and the window layer, and the optical field L of the first embodiment tends to be coupled with the quantum wells of the active layer 15 more at the middle position of the active layer 15, and both of the upper half and the lower half of the active layer 15 can be utilized effectively, and the vertical deviation of the optical field can be compensated to achieve the effects of increasing the modal gain, reducing the threshold current value, making the light emitting element 100 able to be operated at a high temperature condition, and providing a high operating speed. (4) The first embodiment uses the tunnel junction layer TJ to convert the window layer 18 into the n-type, and the window layer 18 is silicon doped, so that the magnesium doping of the window layer of the Comparative Example 1 is no longer needed. As described above, the use of magnesium doping easily has a memory effect that makes it difficult to control and maintain the background environment, concentration setting parameter, and related process conditions in the reaction chamber of the epitaxy process. Therefore, the first embodiment can control the manufacturing process more easily than the Comparative Example 1. In addition, the window layer 18 of the first embodiment is silicon doped, and the silicon doping epitaxy process has an easiness and a stability greater than those of the magnesium doping, so that the silicon doping concentration of the first embodiment can reach 1.0×10¹⁸ atoms/cm³, but the magnesium doping concentration of the Comparative Example 1 can only reach 9.0×10¹⁷ atoms/cm³. Since a high doping concentration is conducive to lowering the resistance, the resistance value of the window layer 18 of the first embodiment is obviously lower than the resistance value of the window layer of the Comparative Example 1. In other words, the window layer 18 of the first embodiment has a better current spreading effect and improves the light emitting efficiency of the first embodiment. (5) The upper electrode 19 of the first embodiment is converted into the n-type and doped by Si/Te (with a concentration greater than 5.0×10¹⁸ atoms/cm³), so that the high doping concentration (1.0×10¹⁹ atoms/cm³) for the carbon doping of the upper electrode of the Comparative Example 1 is no longer needed. As described above, the high carbon doping concentration for the manufacturing process cannot be controlled easily. The first embodiment adopting a lower doping concentration can control the manufacturing process more easily than the Comparative Example 1 adopting a higher doping concentration and can reduce the required concentration.

It is noteworthy that if the first conductive type is n-type, then the second conductive type will be p-type; or if the first conductive is p-type, then the second conductive type will be n-type. Preferably, the first conductive type is n-type, and the second conductive type is p-type. The DBR layer 12 can also be substituted by a metal reflective layer. For example, the metal reflective layer is bonded to the bottom of the lower cladding layer 13. In a first implementation mode, the structure of the light emitting element 100 includes the substrate 11, the metal reflective layer, the lower cladding layer 13, the lower confinement layer 14, the active layer 15, the upper confinement layer 16, the upper cladding layer 17, the tunnel junction layer TJ, the window layer 18 and the upper electrode 19, which are sequentially arranged from bottom to top. Of course, the metal reflective layer may be omitted, and the lower cladding layer 13 is disposed at the top of the substrate 11 and contacted with an upper surface of the substrate 11.

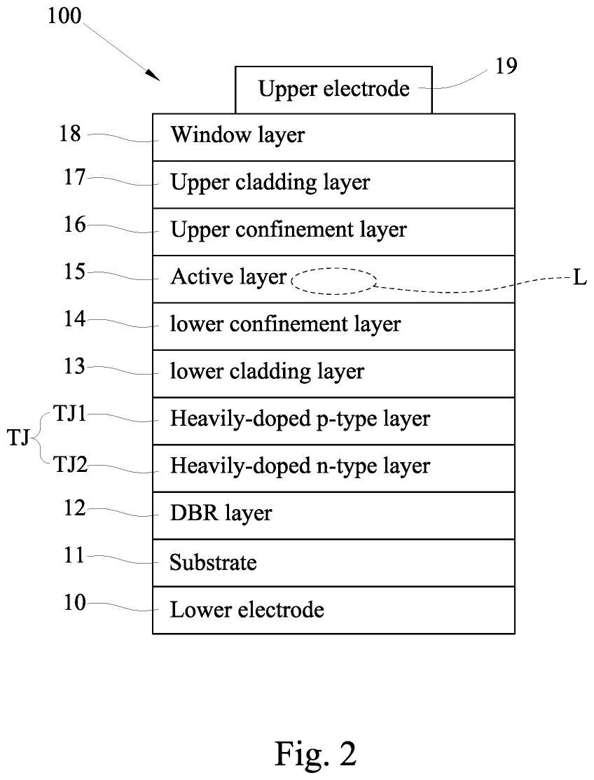

With reference to FIG. 2 for a second implementation mode, the light emitting element 100 includes the lower electrode 10; the substrate 11 contacted with the lower electrode 10 and disposed at the top or the bottom of the lower electrode 10; the DBR layer 12 disposed at the top of the substrate 11 disposed at the top of the DBR layer 12 and contacted with an upper surface of the substrate 11; the tunnel junction layer TJ disposed at the top of the DBR layer 12 and contacted with an upper surface of the DBR layer 12; the lower cladding layer 13 disposed at the top of the tunnel junction layer TJ and contacted with an upper surface of the tunnel junction layer TJ; the lower confinement layer 14 disposed at the top of the lower cladding layer 13 and contacted with an upper surface of the lower cladding layer 13; the active layer 15 disposed at the top of the lower confinement layer 14 and contacted with an upper surface of the lower confinement layer 14; the upper confinement layer 16 disposed at the top of the active layer 15 and contacted with an upper surface of the active layer 15; the upper cladding layer 17 disposed at the top of the upper confinement layer 16 and contacted with an upper surface of the upper confinement layer 16; the window layer 18 disposed at the top of the upper cladding layer 17 and contacted with an upper surface of the upper cladding layer 17; and the upper electrode 19 disposed at the top of the window layer 18 and contacted with an upper surface of the window layer 18. In other words, the structure of the light emitting element 100 in accordance with the second implementation mode includes the substrate 11, the DBR layer 12, the tunnel junction layer TJ, the lower cladding layer 13, the lower confinement layer 14, the active layer 15, the upper confinement layer 16, the upper cladding layer 17, the window layer 18 and the upper electrode 19 sequentially grown from bottom to top by epitaxy. Of course, the DBR layer 12 may be omitted, and the tunnel junction layer TJ is disposed at the top of the substrate 11 and contacted with an upper surface of the substrate 11.

The first electrode 10 is a first conductive electrode such as an n-type electrode. The substrate 11 is a first conductive substrate such as an n-type substrate. The DBR layer 12 is a first conductive DBR layer such as an n-type DBR layer. The heavily-doped p-type layer TJ1 of the tunnel junction layer TJ is disposed adjacent to and at the top of the heavily-doped n-type layer TJ2. In other words, the second heavily-doped layer is disposed adjacent to and at the top of the first heavily-doped layer. The heavily-doped n-type layer TJ2 of the tunnel junction layer TJ is disposed at the top of the DBR layer 12. For example, the heavily-doped n-type layer TJ2 of the tunnel junction layer TJ is disposed adjacent to and at the top of the DBR layer 12; and the lower cladding layer 13 is disposed adjacent to and at the top of the heavily-doped p-type layer TJ1.

The lower cladding layer 13 is a second conductive cladding layer such as a p-type cladding layer. The upper cladding layer 17 is a first conductive cladding layer such as an n-type cladding layer. The window layer 18 is a first conductive window layer such as an n-type window layer. The upper electrode 19 is a first conductive electrode such as an n-type electrode.

Similar to the aforementioned first implementation mode, the DBR layer 12 can also be substituted by a metal reflective layer. For example, the metal reflective layer is bonded to the bottom of the lower cladding layer 13. In the second implementation mode, the structure of the light emitting element 100 includes: the substrate 11, the metal reflective layer, the tunnel junction layer TJ, the lower cladding layer 13, the lower confinement layer 14, the active layer 15, the upper confinement layer 16, the upper cladding layer 17, the window layer 18 and the upper electrode 19, which are sequentially arranged from bottom to top. Of course, the metal reflective layer may be omitted, and the tunnel junction layer TJ is disposed at the top of the substrate 11 and contacted with an upper surface of the substrate 11.

Table 3 lists the structural comparison of a light emitting element 100 in accordance with the second embodiment of the present disclosure (Second Implementation Mode).

TABLE 3
(Second Embodiment)

| | | | | Dopant Content | |
|---|---|---|---|---|---|
| Layer | Description | Material | Dopant | (atoms/cm³) | Type |
| 1 | Lower electrode | GaAs | Si | Greater than | n |
| | | | | 1.0 × 10¹⁸ | |
| 2 | Substrate | GaAs | Si | Greater than | n |
| | | | | 1.0 × 10¹⁸ | |
| 3 | DBR layer | AlGaAs | Si | 6.0 × 10¹⁷ | n |
| Tunnel | Heavily-doped | InGaP | Te | Greater than | n |
| Junction | n-type layer | | | 5.0 × 10¹⁹ | |
| Layer | Heavily-doped | GaAs | C | Greater than | p |
| | p-type layer | | | 5.0 × 10¹⁹ | |
| 4 | Lower cladding | AlInP | Mg | 9.0 × 10¹⁷ | p |
| | layer | | | | |
| 5 | Lower confinement | (Al_{0.65}Ga_{0.35})_{0.5}In_{0.5}P | — | — | — |
| | layer | | | | |
| 6 | Active layer | (Al_{0.65}Ga_{0.35})_{0.5}In_{0.5}P | — | — | — |
| 7 | Upper confinement | (Al_{0.65}Ga_{0.35})_{0.5}In_{0.5}P | — | — | — |
| | layer | | | | |
| 8 | Upper cladding | Al_{0.5}In_{0.5}P | Si | 9.0 × 10¹⁷ | n |
| | layer | | | | |
| 9 | Window layer | GaP | Si | 1.0 × 10¹⁸ | n |
| 10 | Upper | GaP | Si/Te | Greater than | n |
| | electrode | | | 5.0 × 10¹⁸ | |

In the second embodiment, the n-i-p semiconductor junction form of the traditional LED is converted into the p-i-n form, and the light emitting element 100 in accordance with the second embodiment of the present disclosure (Table 3) is compared with the traditional LED of the Comparative Example 1 (Table 1a), wherein the second embodiment adds the tunnel junction layer TJ between the DBR layer and the lower cladding layer of the Comparative Example 1. Compared with the Comparative Example 1, the second embodiment has the following advantages: (1) The tunnel junction layer TJ of the second embodiment converts the p-type window layer of the Comparative Example 1 into the n-type window layer (which is the aforementioned window layer 18) of the second embodiment. Since the n-type window layer has a resistance much smaller than the resistance of the p-type window layer, the window layer 18 of the second embodiment has a low resistance and a good current spreading effect to improve the light emitting efficiency of the second embodiment. (2) Since the window layer 18 of the second embodiment is an n-type window layer, the upper electrode 19 is also an n-type electrode. In other words, the tunnel junction layer TJ also converts the p-type upper electrode of the Comparative Example 1 into the n-type upper electrode (which is the aforementioned upper electrode 19) of the tunnel junction layer TJ of the second embodiment. The n-type upper electrode has a resistance much smaller than the resistance of the p-type upper electrode, so that the upper electrode 19 (or n-type upper electrode) of the second embodiment is more conducive to the ohmic contact compared with the upper electrode (or p-type upper electrode) of the Comparative Example 1. (3) Unexpectedly, it is found that the mobility of carriers in the n-type semiconductor is greater than the mobility of carriers in the p-type semiconductor, so that the electrons/electron holes are coupled to the upper half of the active layer of the Comparative Example 1 to emit light, such that most of the optical field L is deviated at the upper half of the active layer and the lower half of the active layer cannot be utilized effectively. On the other hand, the second embodiment uses the tunnel junction layer TJ to convert the upper cladding layer 17, the window layer 18 and the upper electrode 19 into the n-type, and thus the carriers of the second embodiment from top to bottom has a mobility at the upper electrode 19, the window layer 18 and the upper cladding layer 17 greater than the mobility of the carriers of the Comparative Example 1 from top to bottom at the upper electrode and the window layer, and the optical field L of the second embodiment tends to be coupled with the quantum wells of the active layer 15 more at the middle position of the active layer 15, and both of the upper half and the lower half of the active layer 15 can be utilized effectively, and the vertical deviation of the optical field can be compensated to achieve the effects of increasing the modal gain, reducing the threshold current value, making the light emitting element 100 able to be operated at a high temperature condition, and providing a high operating speed. In addition, when the second embodiment is compared with the first embodiment, the upper cladding layers 17 of the second embodiment and the first embodiment are of n-type and p-type respectively, so that the carriers of the second embodiment has a mobility from top to bottom at the upper electrode 19, the window layer 18 and the upper cladding layer 17 greater than the mobility of the carriers of the first embodiment from top to bottom, such that the optical field L of the second embodiment tends to be coupled with the quantum wells of the active layer 15 more at the middle position of the active layer 15 and both of the upper half and the lower half of the active layer 15 can be utilized effectively, and the vertical deviation of the optical field can be compensated to achieve the effects of increasing the modal gain, reducing the threshold current value, making the light emitting element 100 able to be operated at a high temperature condition, and providing a high operating speed. (4) The second embodiment uses the tunnel junction layer TJ to convert the window layer 18 into the n-type, and the window layer 18 is silicon doped, so that the magnesium doping of the window layer of the Comparative Example 1 is no longer needed. As described above, the use of magnesium doping easily has a memory effect that makes it difficult to control and maintain the background environment, concentration setting parameter, and related process conditions in the reaction chamber of the epitaxy process. Therefore, the second embodiment can control the manufacturing process more easily than the Comparative Example 1. In addition, the window layer 18 of the second embodiment the window layer 18 is silicon doped, and the silicon doping epitaxy process has an easiness and a stability greater than those of the magnesium doping, so that the silicon doping concentration of the second embodiment can reach 1.0×10¹⁸ atoms/cm³, but the magnesium doping concentration of the Comparative Example 1 can only reach 9.0×10¹⁷ atoms/cm³. Since a high doping concentration is conducive to lowering the resistance, the resistance value of the window layer 18 of the second embodiment is obviously lower than the resistance value of the window layer of the Comparative Example 1. In other words, the window layer 18 of the second embodiment has a better current spreading effect and improves the light emitting efficiency of the second embodiment. (5) The upper electrode 19 of the second embodiment is converted into the n-type and doped by Si/Te (with a concentration greater than 5.0×10¹⁸ atom s/cm³), so that the high doping concentration (1.0×10¹⁹ atoms/cm³) for the carbon doping of the upper electrode of the Comparative Example 1 is no longer needed. As described above, the high carbon doping concentration for the manufacturing process cannot be controlled easily. The second embodiment adopting a lower doping concentration can control the manufacturing process more easily than the Comparative Example 1 adopting a higher doping concentration and can reduce the required concentration.

In the present disclosure, the light emitting element is disposed between the upper cladding layer and the window layer, or the tunnel junction layer is disposed between the DBR layer and the lower cladding layer. The tunnel junction layer is provided for converting the window layer and upper electrode from the p-type of the traditional LED into the n-type of the present disclosure. Since the n-type window layer has a resistance much smaller than the resistance of the p-type window layer, the window layer of the light emitting element of the present disclosure has a low resistance and a good current spreading effect to improve the light emitting efficiency. Since the n-type upper electrode has a resistance much lower than the resistance of the p-type upper electrode, the n-type upper electrode of the light emitting element of the present disclosure is more conducive to ohmic contact than the p-type upper electrode of the traditional LED. The carriers in the n-type semiconductor has a mobility greater than the mobility of the carriers in the p-type semiconductor, so that the carriers of the emitting element of the present disclosure light has a mobility from top to bottom at the n-type upper electrode and the n-type window layer 18 greater than the mobility of the carriers of the traditional LED from top to bottom at the upper electrode and the window layer, and the optical field L in the light emitting element of the present disclosure tends to be coupled with the quantum wells of the active layer more at the middle position of the active layer. Compared with the traditional LED having most of the optical field deviated at the upper half of the active layer, the light emitting element of the present disclosure can use both of the upper half and the lower half the active layer effectively. The window layer of the light emitting element of the present disclosure can use silicon to substitute the magnesium of the traditional LED having the memory effect, and the upper electrode can use Si/Te to substitute the high carbon doping concentration of the traditional LED, so that the manufacturing process of the light emitting element of the present disclosure can be controlled more easily than the traditional LED.

What is claimed is:

1. A light emitting element, comprising:
a substrate;
a lower cladding layer, disposed at top of the substrate;
a lower confinement layer, disposed at top of the lower cladding layer;
an active layer, disposed at top of the lower confinement layer;
an upper confinement layer, disposed at top of the active layer;
an upper cladding layer, disposed at top of the upper confinement layer;
a tunnel junction layer, disposed at top of the upper cladding layer; and
a window layer, being an n-type window layer, disposed at top of the tunnel junction layer.

2. The light emitting element according to claim 1, wherein the tunnel junction layer comprises a heavily-doped p-type layer and a heavily-doped n-type layer, and the heavily-doped n-type layer is disposed adjacent to and at top of the heavily-doped p-type layer.

3. The light emitting element according to claim 2, wherein the heavily-doped p-type layer is disposed at the top of the upper cladding layer, and the window layer is disposed adjacent to and at top of the heavily-doped n-type layer.

4. The light emitting element according to claim 3, wherein an upper electrode and the window layer form an ohmic contact and the upper electrode is an n-type electrode.
